(19) United States
(12) Patent Application Publication
(10) Pub. No.: US 2010/0262886 A1
(43) Pub. Date: Oct. 14, 2010

(54) SELECTIVE DECODING OF RE-TRANSMITTED DATA BLOCKS

(75) Inventor: Jing-Fei Ren, Plano, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/420,964

(22) Filed: Apr. 9, 2009

(51) Int. Cl. H04L 1/08; G06F 11/14; H03M 13/05; G06F 11/10

(52) U.S. Cl. 714/751; 714/748; 714/799; 714/E11.032; 714/E11.131

(57) ABSTRACT

In at least some embodiments, a method includes receiving a transport block transmission having a plurality of code words and decoding the code words. The method also includes testing each decoded code word to identify each code word as a good code word or a bad code word. During a subsequent retransmission of the transport block, the method includes repeating the decoding and the testing for previously identified bad code words, but not for previously identified good code words.

### BACKGROUND

The telecommunications industry has used the Automatic Repeat Request (ARQ) layer 2 protocol for many years to ensure that data is sent reliably from one node to another. In regular ARQ, error-detecting (ED) codes such as cyclical redundancy checking (CRC) and a sliding window are used to identify when an error has occurred in a transmission. If errors are detected, the receiving node requests a retransmission from the source node.

During good radio conditions, ARQ can be considered very efficient, as no additional forward error correction (FEC) bits are added to the basic data to be transmitted. Yet bandwidth efficiency will suffer significantly in poor channel conditions due to excessive retransmissions. Hybrid ARQ (HARQ) performs better than regular ARQ in poor signal conditions, but in its simplest form, this comes at the expense of significantly lower throughput in good signal conditions. There is typically a signal quality crossover point below which simple HARQ is most efficient and above which basic ARQ is the best solution.

The simplest version of HARQ, Type I HARQ, in addition to ED adds FEC information to each message prior to transmission. If channel quality is sufficiently good, all transmission errors should be correctable and the receiver can decode the data block correctly. If the channel quality is poor and not all transmission errors can be corrected, the data block will be discarded and the receiver (similar to ARQ) will request a retransmission. Although ED adds only a few bits to each transmission, the additional FEC bits will add significant overhead to each transmission. In periods of good channel quality, it will significantly reduce the user data rate and therefore the bandwidth efficiency.

Type II HARQ is a more sophisticated solution that transmits a subset of the data, ED, and FEC bits on a given transmission. Successive transmissions include a different subset of these bits. In Type II HARQ, the first transmission contains enough data, ED, and FEC bits to decode the transmission in good channel conditions, but not in poor conditions. If this first transmission is received error-free, the transmitting node will prepare and transmit the next block of data. If the data from the first transmission is received in error, though, the second transmission will contain a different set of data, ED, and FEC bits. If received error-free, the transmitting node will prepare and transmit the next block of data. Error correction can be attempted by combining the information received from both the first and second transmissions in a process known as incremental redundancy (IR). Each subsequent transmission is combined with earlier transmissions until the packet is received correctly.

Only Type I HARQ suffers the capacity loss when channel quality is good. Type II HARQ does not, because the code rate is iteratively reduced on subsequent retransmissions only if necessary. When channel quality is good, Type II HARQ obtains similar channel capacity as standard ARQ, eliminating unnecessary bandwidth inefficiencies.

Type 11 HARQ uses a mother code that can be punctured to achieve the desired code rate. Currently, for LTE, this mother code is a rate 1/3 turbo code. This code contains systematic bits, which means the input and ED bits are present verbatim in the output. The first transmission of the packet would send mostly these systematic bits by puncturing out most of the FEC bits. Subsequent retransmissions would send fewer of the systematic bits and more of the FEC bits.

The different transmitted versions of the packet containing different combinations of systematic and FEC bits are called redundancy versions (RVs). LTE uses four RVs that are repeatedly sequenced through until the packet is received correctly or until a maximum number of retransmissions have been sent, at which time HARQ declares a failure and leaves it up to ARQ running in radio link control (RLC) to try again.

HARQ uses a stop and wait protocol. When a transmission has been made, the transmitting entity stops and waits until it receives an acknowledgment (ACK) or negative acknowledgement (NACK) back from the destination before transmitting the next block of data or retransmitting the same data block. In either case (ACK or NACK), the transmitting entity is required to schedule and process the next transmission within a specific time period.

Currently, for LTE frequency-division duplex (FDD) on the uplink, this time has been set to eight 1-ms subframes. Since it only takes one subframe to transmit the data, this results in seven subframes of unutilized bandwidth. To fully utilize this bandwidth, LTE uses multiple HARQ parallel processes offset in time from each other. Each process transmits a block of data. By the time its next transmission allocation arrives, it will have already received the ACK or NACK from the receiving entity and created the next packet for transmission or retransmission. It should be noted that LTE time-division duplex (TDD) supports a configurable number of HARQ processes and the timing requirements aren't fully defined as of 36.213 v8.3.0.

For FDD, there are exactly eight uplink HARQ processes, while the downlink can have up to eight. Downlink HARQ processes can be transmitted in any order without fixed timing (asynchronous HARQ), whereas each uplink HARQ process is assigned to a specific subframe (synchronous HARQ). The user equipment (UE) transmits within the same HARQ process every eighth subframe.

LTE uses asynchronous Type II HARQ transmission on the downlink. In other words, the receiver doesn't know ahead of time what's being transmitted (or when), so the HARQ process identifier and the RV must be sent along with the data. The RV specifies which combination of data, ED, and FEC bits is being sent to the UE. This is done through the physical downlink shared channel (PDSCH) resource allocation messages sent on a physical downlink control channel (PDCCH) simultaneous to the corresponding PDSCH transmission. The advantage of this scheme is that the scheduling algorithm has considerable freedom in deciding which UEs are sent data during any subframe.

In contrast, LTE uses synchronous HARQ transmission on the uplink. In other words, the base station (eNodeB) knows exactly which HARQ process and RV the UE will transmit ahead of time. So, this information doesn't have to be included in the PDCCH message providing the uplink scheduling information to the UE. Synchronous HARQ can be used because the UE transmits the same HARQ process every eighth subframe. Because retransmissions of a HARQ process are associated with previous transmissions based on the eight-subframe delay, the scheduling in the uplink is not quite as flexible as that in the downlink.

Adaptive modulation and coding (AMC) attempts to match the transmissions from a HARQ process to the channel conditions. Under strong signal conditions, less redundancy and/or a higher-order modulation format is employed in the initial transmission, enabling a higher user data rate for a given bandwidth. Under weak signal conditions, more redundancy bits are used and/or a lower-order modulation format is used to improve the probability of reception. However, this lowers the user data rate. If the error rate is zero, then it is likely that too much protection is being applied. Alternatively, if insufficient protection is applied, the same data will be retransmitted, effectively wasting valuable network resources. The ideal situation is where data throughput is maximized at an error rate that is relatively low but greater than zero.

As with W-CDMA, the LTE base station decides on the modulation coding scheme (MCS), depending on information the UE sends in the channel quality indicator (CQI). LTE, though, is more complicated than W-CDMA/HSPA, which requires only a single CQI value to be transmitted. Unlike WCDMS/HSPA, LTE allows a single shared channel transmission to occur on a subset of the possible subcarriers. Given the wide bandwidths provided by LTE, some of the subcarriers could be in fading nulls at the same time others can be received clearly. CQI information from the UE provides channel information measured per subband or wideband.

The network's scheduling algorithm can use subband CQI to assign subchannel resources for optimum transmission. If the channel characteristics change considerably after the initial transmission, the Medium Access Control (MAC) layer is free to assign a different set of subchannels on subsequent transmissions, or to abort that transmission and start a new one using a more appropriate modulation and coding scheme.

LTE uses a clever algorithm to implement incremental redundancy and adaptive coding. The systematic bits from the turbo encoder are interleaved and placed into a circular buffer called the soft buffer. The redundancy bits are then interleaved and placed after the systematic bits. All the redundancy bits are included in the soft buffer used on uplink transmissions, but upper layers define the number of redundancy bits included for downlink transmissions.

Bits are copied from the buffer starting at a position that depends on the RV. The starting position for RVₙ is approximately n/4 of the way around the circular buffer, plus a fixed offset of two interleave rows. The number of bits pulled from the circular buffer for each RV depends on the target code rate. For poor channel conditions, the code rate approaches 0.1, in which case the entire soft buffer is transmitted multiple times each RV. In excellent channel conditions, the code rate approaches 0.92, which means the number of bits transmitted in each RV is slightly more than the number of bits in the transport block.

LTE also runs a semi-independent ARQ process at the RLC layer, just above the MAC in the protocol stack, which can be improved with some help from the MAC. “Local NACK,” as it is sometimes known, uses information from the physical layer (PHY) and MAC using the HARQ processes to inform the transmitting RLC entity of missing protocol data units (PDUs) before the data-receiving RLC entity can detect they're missing. This significantly reduces latency by having the lost RLC PDUs retransmitted much earlier than if the RLC ARQ were used in isolation.

The LTE specifications impose constraints on the UE and the base station regarding the amount of time they have to complete the HARQ process. Currently, the receiver has three subframes to decode the transmission, check the CRC, and encode the ACK/NACK. Assuming the transmitter sent the data in subframe n, the ACK/NACK must be sent back to the transmitter in subframe n+4. Currently, the transmitter has three subframes to decode the ACK/NACK returned from the receiver, construct the next transport block(s) based on the ACK/NACK (this is a job for the RLC and MAC), and encode the transport block(s). The next transport block(s) are transmitted on this HARQ process in subframe n+8 in the uplink or potentially earlier for the downlink.

Given that a different HARQ process utilizes each subframe, certain assumptions regarding the execution times allowed for each of the processing steps can be made. Assuming only one processing unit for each step is multiplexed in time between all HARQ processes, the computations associated with each step cannot exceed 1 ms. If one of the steps exceeded 1 ms, it would not be able to keep up with the continuous flow of HARQ information in each subframe. Drawing some comparisons to W-CDMA/HSPA, the current transmission time interval (TTI) for HSPA is 2 ms, and the TTI for LTE will be 1 ms. The current HSPA UL HARQ turnaround time (transmit, received ACK/NACK, transmit again) is a minimum of 16 ms. This reduces to 8 ms for LTE.

In summary, type 11 HARQ and AMC work together to provide a very adaptive transport mechanism in LTE. AMC tunes the initial HARQ transmission to use a coding rate that will result in approximately the ideal frame error rate from a throughput perspective. Type II HARQ then uses incremental redundancy to add FEC bits in each successive retransmission, reducing the effective code rate until the packet can be decoded correctly. The result, although not perfect, attempts to optimize the overall throughput over wide ranges of dynamically changing channel conditions. Even so, LTE decoders consume a significant amount of power. For example, an LTE decoder may account for approximately 25% of the total power consumption of an LTE modem at peak data rate.

### SUMMARY

In at least some embodiments, a method comprises receiving a transport block transmission having a plurality of code words and performing a test to identify each code word as a good code word or a bad code word. During a subsequent retransmission of the transport block, the method comprises repeating the test for previously identified bad code words, but not for previously identified good code words.

In at least some embodiments, an electronic device comprises a processor and a receiver coupled to the processor. The receiver provides an iterative decode function that, for each of multiple transmissions of a set of data blocks, performs a decode with forward error correction (FEC) bits added for each transmission, performs a test to identify valid data blocks, stores the valid data blocks, and stores identifiers to avoid decoding and testing re-transmitted data blocks previously identified as valid data blocks.

In at least some embodiments, a receiver comprises decode and test logic that identifies each of a plurality of data blocks as a good data block or a bad data block. The receiver also comprises a re-sequencing buffer that stores good data blocks, but not bad data blocks. The re-sequencing buffer selectively re-orders the good data blocks

### BRIEF DESCRIPTION OF THE DRAWINGS

For a detailed description of various embodiments of the invention, reference will now be made to the accompanying drawings in which:

FIG. 1 shows a system in accordance with an embodiment of the disclosure;

FIG. 2 shows a receiver in accordance with an embodiment of the disclosure; and

FIG. 3 shows a method in accordance with an embodiment of the disclosure.

### NOTATION AND NOMENCLATURE

Certain terms are used throughout the following description and claims to refer to particular system components. As one skilled in the art will appreciate, computer companies may refer to a component by different names. This document doe not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct electrical connection. Thus, if a first device couples to a second device, that connection may be through a direct electrical connection, or through an indirect electrical connection via other devices and connections. The term “system” refers to a collection of two or more hardware and/or software components, and may be used to refer to an electronic device or devices or a sub-system thereof.

### DETAILED DESCRIPTION

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

Embodiments of the disclosure are directed to communication systems that implement Hybrid Automatic Repeat Request (HARQ) technology or other repeat transmission technologies. As described herein, a set of data blocks are transmitted and, if necessary, re-transmitted between a transmitting unit (e.g., a base station) and a receiving unit (e.g., user equipment). The set of data blocks may be, for example, a unit that needs to be delivered in its entirety to higher layer processes in the received. Rather than discarding an entire set of decoded data blocks when some of the decoded data blocks fall below a desired quality threshold, embodiments store the “good” decoded data blocks and discard the “bad” decoded data blocks. As used herein, “good” data blocks meet a predetermined quality threshold (e.g., quantity of errors or passing an error detection test) and “bad” data block fall below the predetermined quality threshold. By storing good decoded data blocks, various processing steps need not be repeated during retransmissions of a data block set (or partial data block set). Additionally, information (e.g., soft bits) related to the bad data blocks can be stored and iteratively used to improve the probability that bad data blocks will be decoded correctly during subsequent retransmissions. On the other hand, soft bits for the good blocks need not be stored. In various circumstances, the disclosed techniques improve the efficiency of repeat transmission technologies.

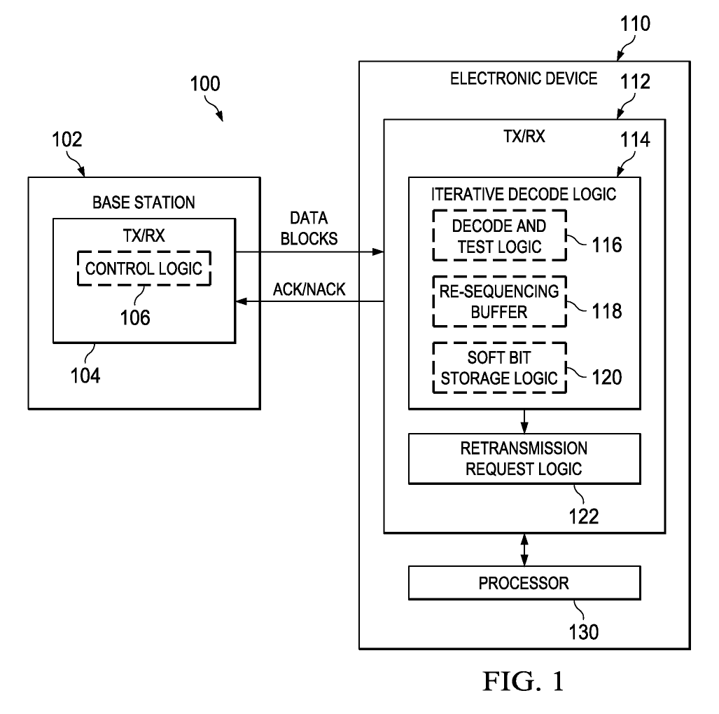

FIG. 1 shows a system 100 in accordance with an embodiment of the disclosure. As shown, the system 100 comprises a base station 102 in communication with an electronic device 110. The base station 102 comprises a transceiver (TX/RX) 104 having control logic 106. In operation, the control logic 106 enables the transceiver 104 to transmit data blocks to the electronic device 110 and to process acknowledgements (ACKs/NACKs) from the electronic device 110 in accordance with the LTE protocol or another protocol that employs Hybrid Automatic Repeat Request (HARQ) technology.

As shown, the electronic device 110 comprises a processor 130 coupled to a transceiver 112. In operation, the electronic device 200 performs various functions by providing instructions/data to the processor 204 for execution. In part, these instructions/data may be stored in a memory (not shown) accessible to the processor 130. Additionally or alternatively, instructions/data may be transmitted to the electronic device 110 and received by the transceiver 112 for subsequent execution by the processor 130 or for use with an application being executed by the processor 130.

As shown, the transceiver 112 comprises iterative decode logic 114. In accordance with at least some embodiments, the iterative decode logic 114 receives multiple transmissions of a data block set (e.g., a transport block with multiple code words). For each of multiple transmissions of the data block set, the iterative decode logic 114 performs a decode with forward error correction (FEC) bits added for each transmission, performs a test to identify valid data blocks, stores the valid data blocks, and stores identifiers to avoid re-decoding re-transmitted data blocks previously identified as valid data blocks. In accordance with embodiments, the iterative decode logic 114 generates probability data for each bit to be decoded (i.e., FEC bits). The probability data is stored for use during subsequent transmissions of the set of data blocks (e.g., to improve data block decoding).

As shown in FIG. 1, the iterative decode logic 114 comprises decode and test logic 116, a re-sequencing buffer 118 and soft bit storage logic 120. In operation, the decode and test logic 116 provides the bust guess of the original data blocks sent by a transmitting unit based on soft bits. The decode and test logic 116 also identifies good (valid) decoded data blocks and bad (invalid) decoded data blocks. As previously mentioned, good data blocks meet a predetermined quality threshold (e.g., quantity of errors, passing an error detection test, or convergence of iterative decoding results) and bad data blocks do not meet the predetermined quality threshold. For example, in at least some embodiments, the test logic 116 performs a cyclic redundancy check (CRC) to identify good data blocks and bad data blocks. If all received data blocks in a set are identified as good data blocks, the data block set is passed as a unit to subsequent processing layers of transceiver 112 for further operations on the data block set (e.g., Media Access Control (MAC) layer operations). More specifically, if during a first transmission, all received data blocks in the set are identified as good data blocks, there is no need to store the decoded data blocks in the re-sequencing buffer 118. Also, there is no need to store the soft bits. However, if at least one re-transmission is needed before all received data blocks in the set are identified as good data blocks, the re-sequencing buffer 118 is used to store good data blocks and to re-sequence (re-order) data blocks in the set as needed. The re-sequencing process may occur, for example, when the re-sequencing buffer receives a control signal indicating that a bad data block from a previous transmission is now decoded as a good data block (although out of order). Subsequent to any re-sequencing operation, other receive operations (e.g., MAC layer operations) are performed on the data block set.

In the event re-transmissions are not needed, the transceiver 112 transmits an ACK packet to the base station 102 to confirm successful receipt of the data block set. In the event that re-transmissions are needed, the iterative decode logic 114 notifies the re-transmission request logic 122, which causes a NACK packet to be transmitted to the base station 102. In some embodiments, the NACK packet causes the base station 102 to re-transmit the entire data block set to the electronic device 110. Alternatively, the NACK packet provides sufficient information to enable the base station 102 to re-transmit only data blocks in the set that were identified as bad data blocks by the iterative decode logic 114. In either case, the iterative decode logic 114 is able to re-decode and re-test data blocks previously identified as bad data blocks and to avoid decoding and testing data blocks previously identified as good data blocks. The process of testing data blocks, storing good data blocks, and requesting re-transmission can be repeated until good copies of all data blocks of a set have been received or until a predetermined time has passed at which point transmission of the data block set has failed. In such case, modification may be made to the transmission scheme to improve reception of a data block set. As an example, such modifications may include increasing transmission power, increasing redundancy bits, or other techniques to improve reception (e.g., lower order modulation or reducing the data block sizes).

As shown in FIG. 1, the iterative decode logic 114 also comprises soft bit storage logic 120. In accordance with at least some embodiments, the soft bit storage logic 120 receives probability information regarding the value (“0” or “1”) for each bit being decoded from the decode and test logic 116. For example, the probability information may correspond to soft bits generated based on a log-likelihood ratio (LLR) algorithm or another algorithm that conveys probability information regarding the value (“0” or “1”) for each bit being decoded. Even if the decode and test logic 116 determines that a given data block is a bad data block, the soft bits for the given data block may be stored in the soft bit storage logic 120. For each re-transmission of a bad data block, additional soft bits are generated by the decode and test logic 116 and are combined with the soft bits stored in the soft bit storage logic 120. The combining and accumulation of soft bits during multiple re-transmissions improves the probability of determining a correct value for each bit being decoded. In summary, both storing the accumulation of good data blocks and the combining and accumulation of soft bits during multiple re-transmissions of a bad data block set (or a partial data block set) function to statistically decrease the number of re-transmissions needed before all data blocks in a set will be received and decoded correctly (as compared to not storing good data blocks and/or soft bits).

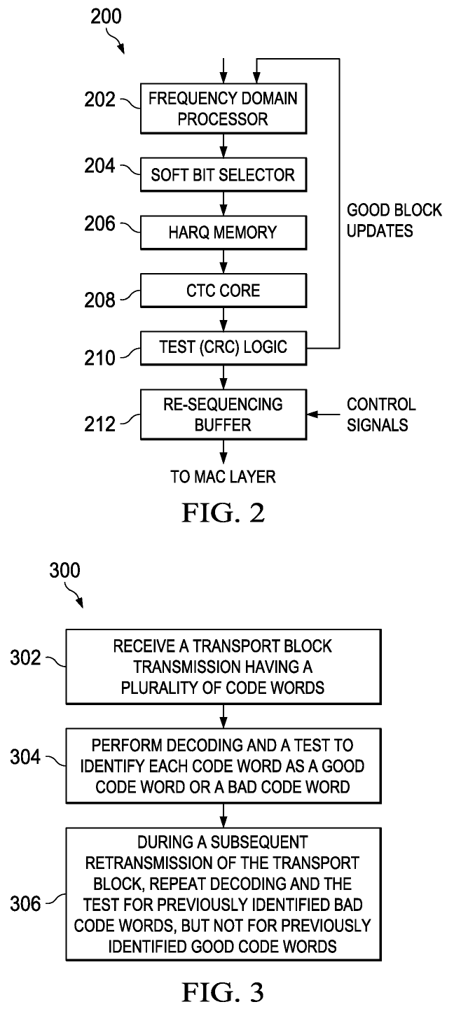

FIG. 2 shows a receiver 200 in accordance with an embodiment of the disclosure. The receiver 200 may be implemented, for example, as part of the transceiver 112 described for FIG. 1. As shown, the receiver 200 comprises a frequency domain processor 202 that receives data blocks and processes the data blocks in the frequency domain. In accordance with at least some embodiments, the frequency domain processor 202 generates soft bits for each data bit to be decoded. The frequency domain processor 202 also may determine whether a previous transmission of a data block has been identified as a good data block or a bad data block. In the event a previous transmission of a data block has been identified as a good data block, the frequency domain processor 202 foregoes further processing a current transmission of the same data block. During multiple re-transmissions of a data block set (or partial data block set), the frequency domain processor 202 receives updated information (“good block updates”) regarding good data blocks identified by test logic 210. Thus, the frequency domain processor 202 operates to generate soft bits for data blocks that have not yet been identified as good or bad (e.g., during an initial transmission) and for re-transmitted data blocks previously identified as bad data blocks. By avoiding the re-processing of good data blocks, some amount of power is conserved by the receiver 200 (compared to re-processing each re-transmission of a data block set).

Soft bits generated by the frequency domain processor 202 are provided to the soft bit selector 204, which selects a soft bit for output to the HARQ memory 206. In at least some embodiments, the soft bit selector 204 buffers soft bits received from the frequency domain processor 202 and provides the soft bits in a first-in first-out (FIFO) manner. During multiple re-transmissions of a data block set (or partial data block set), the HARQ memory 206 stores old (previous transmissions of a data block set) and new soft bits (a current transmission of a data block set) and outputs a value associated with each received soft bit to a convolutional turbo code (CTC) decoder core 208. In at least some embodiments, the HARQ memory 206 comprises a set of circular buffers, each being sufficient to handle the largest size transmission (e.g., sufficient to handle a data block having the highest order of modulation) possible for the communication protocol being implemented. Alternatively, the HARQ memory 206 comprises a contiguous memory space that may be subdivided and allocated as needed. In either case, available HARQ memory 206 space is selectively allocated for old/new soft bits. The CTC core 208 performs error correction on received data blocks based on the content of the HARQ memory 206 and outputs error corrected data blocks to the test logic 210, which performs a CRC or another test to identify good (valid) data blocks and bad (invalid) data blocks.

If during a first transmission, all received data blocks in a set (e.g., a transport block having a plurality of code words) are identified as good data blocks, there is no need to store the data blocks in the re-sequencing buffer 212. However, if at least one re-transmission is needed before all received data blocks in a set are identified as good data blocks, the re-sequencing buffer 212 is used to store good data blocks and to re-sequence (re-order) data blocks in the set as needed. The re-sequencing process may occur, for example, when the re-sequencing buffer receives a control signal indicating additional data blocks are decoded and passed the test (i.e., the data blocks are good/valid). Subsequent to the re-sequencing operation (if needed), other receive operations (e.g., MAC layer operations) are performed on the data block set.

In accordance with some embodiments, the re-sequencing buffer 212 is not used for data blocks associated with non-HARQ transport blocks. Further, the re-sequencing buffer 212 may forward stored data blocks to a MAC layer upon receiving a pass signal from the test logic 210 indicating each data block has passed the error (validity) test and a hold signal from the MAC layer indicating the MAC layer is available to receive data from the re-sequencing buffer 212.

FIG. 3 shows a method 300 in accordance with an embodiment of the disclosure. As shown, the method 300 comprises receiving a transport block transmission having a plurality of code words (block 302). At block 304, decoding and a test is performed to identify each code word as a good code word or a bad code word. In at least some embodiments, the test comprises a cyclic redundancy check (CRC). During a subsequent re-transmission of the transport block (or partial transport block), decoding and testing is repeated for bad code words, but not for good code words (block 306).

In at least some embodiments, the method 300 comprises additional or fewer steps. For example, the method 300 may additionally comprise requesting retransmission of previously identified bad codes words, but not previously identified good code words. Further, the method 300 may additionally comprise, storing good code words in a re-sequencing buffer, but not bad code words. Further, the method 300 may additionally comprise selectively re-ordering good code words to reconstruct the transport block. In such case, the re-ordering occurs after a last missing code word is decoded and is identified as a good code word. Further, the method 300 may additionally comprise storing soft bits related to bad code words during a transmission of the transport block and using the soft bits for a decoding function during a retransmission of the transport block. Further, the method 300 may comprise, while a subsequent retransmission of the transport block occurs, performing at least one post-decoding function for good code words, but not bad code words.

The above discussion is meant to be illustrative of the principles and various embodiments of the present invention. Numerous other variations and modifications will become apparent to those skilled in the art once the above disclosure is fully appreciated. It is intended that the following claims be interpreted to embrace all such variations and modifications.

What is claimed is:

1. A method, comprising:
receiving a transport block transmission having a plurality of code words;
decoding the code words;
testing each decoded code word to identify each decoded code word as a good code word or a bad code word; and
during a subsequent retransmission of the transport block, repeating said decoding and said testing for previously identified bad code words, but not for previously identified good code words.

2. The method of claim 1 further comprising requesting retransmission of previously identified bad codes words, but not previously identified good code words.

3. The method of claim 1 further comprising storing good code words in a re-sequencing buffer, but not bad code words.

4. The method of claim 1 wherein said testing comprises performing a cyclic redundancy check (CRC).

5. The method of claim 1 further comprising selectively re-ordering good code words to reconstruct the transport block.

6. The method of claim 5 wherein said re-ordering occurs after a last missing code word is identified as a good code word and is decoded.

7. The method of claim 1 further comprising storing soft bits related to bad code words during a transmission of the transport block and using said soft bits for a decoding function during a retransmission of the transport block.

8. The method of claim 1 further comprising, while a subsequent retransmission of the transport block occurs, performing at least one post-decoding function for good code words, but not bad code words.

9. An electronic device, comprising:
a processor; and
a receiver coupled to the processor, wherein the receiver provides an iterative decode function that, for each of multiple transmissions of a set of data blocks,
performs a decode with forward error correction (FEC) bits added for each transmission,
performs a test to identify valid data blocks,
stores the valid data blocks, and
stores identifiers to avoid decoding and testing re-transmitted data blocks previously identified as valid data blocks.

10. The electronic device of claim 9 wherein the iterative decode function performs a first function that generates FEC bits and wherein the receiver stores the FEC bits for use during subsequent transmissions of the set of data blocks

11. The electronic device of claim 9 wherein the test comprises a cyclic redundancy check (CRC).

12. The electronic device of claim 9 wherein the receiver comprises a re-sequencing buffer to store said valid data blocks.

13. The electronic device of claim 12 wherein, upon receiving a signal that indicates valid versions of all data blocks of said set have been received, the re-sequencing buffer re-orders the stored valid data blocks for output to the processor.

14. The electronic device of claim 9 wherein the receiver distinguishes between valid data blocks and invalid data blocks and requests re-transmission of invalid data blocks, not valid data blocks.

15. A receiver, comprising:
decode and test logic that identifies each of a plurality of data blocks as a good data block or a bad data block; and
a re-sequencing buffer that stores good data blocks, but not bad data blocks,
wherein the re-sequencing buffer selectively re-orders the good data blocks.

16. The receiver of claim 15 wherein the decode and test logic generates soft bits related to bad data blocks and stores said soft bits for use during a retransmission of the bad data blocks.

17. The receiver of claim 15 wherein the decode and test logic performs a cyclic redundancy check (CRC) to identify each of said plurality of data blocks as a good data block or a bad data block.

18. The receiver of claim 15 wherein the plurality of data blocks are code words of a transport block.

19. The receiver of claim 15 wherein the re-sequencing buffer is not used for data blocks associated with non-HARQ transport blocks.

20. The receiver of claim 15 wherein the re-sequencing buffer forwards stored data blocks to a Media Access Control (MAC) layer upon receiving a pass signal from the test logic indicating a good version of each data block has been received and a hold signal from the MAC layer indicating the MAC layer is available to receive data from the re-sequencing buffer.
